(19) United States
(12) Patent Application Publication
(10) Pub. No.: US 2014/0200725 A1
(43) Pub. Date: Jul. 17, 2014

(54) DEVICE AND METHOD FOR DISAGGREGATING A PERIODIC INPUT SIGNAL PATTERN

(71) Applicant: Paulus Henricus Antonius Dillen, Eindhoven (NL)

(72) Inventor: Paulus Henricus Antonius Dillen, Eindhoven (NL)

(73) Assignee: KONINKLIJKE PHILIPS N.V., EINDHOVEN (NL)

(21) Appl. No.: 14/238,220

(22) PCT Filed: Sep. 5, 2012
(86) PCT No.: PCT/IB2012/054567

§ 371 Date: Feb. 11, 2014

Related U.S. Application Data
(60) Provisional application No. 61/533,315, filed on Sep. 12, 2011.

(51) Int. Cl. G01R 21/06

(52) U.S. Cl. CPC G01R 21/06
USPC 700/291

(57) ABSTRACT

The invention relates to a device (10) and a method for disaggregating a periodic input signal pattern (20), the input signal pattern (20) resulting from a superposition of element signal patterns corresponding to respective source elements. The invention further relates to a corresponding computer program. The input signal pattern (20) is processed and outputted. The processed signal pattern (22) is indicative of a change between portions of the input signal pattern (20), wherein such portion corresponds to at least a part of the period of the input signal pattern (20). Based on element information characterizing the element signal patterns and the processed signal pattern (22), a combination (24) of element signal patterns is identified, the superposition of which results in the input signal pattern (20).

### FIELD OF THE INVENTION

The invention relates to a device and a method for disaggregating a periodic input signal pattern, the input signal pattern resulting from a superposition of element signal patterns corresponding to respective source elements. The invention further relates to a corresponding computer program. One particular use of the present invention lies in the field of energy disaggregation, i.e. the identification of loads (and sources) in a power network, in particular in a domestic power network.

### BACKGROUND OF THE INVENTION

In a plurality of contexts there might a need or desire for disaggregating an input pattern into the element patterns which in combination result in the input pattern. An example of such context is energy disaggregation or the process of “energy profiling”.

In the process of so-called energy profiling, an objective is to recognize individual electrical appliances, or classes thereof, from their combined (aggregated) energy consumption pattern. This is theoretically possible though a multitude of properties (also known as features) of the energy consumption pattern.

One conventional approach is to consider the electrical current signal as function of the voltage. Since the voltage is periodic (with 50 Hz or 60 Hz in most countries) and near-stationary in waveshape, the characterization of the current of a specific constant (stationary) load can be reduced to a single-current-cycle approach. In other words, for constant loads, their single-cycle current pattern can be used as characteristic feature, as it is illustrated in FIG. 1, which shows exemplary current cycle waveshapes for various appliances (with the abscissa indicating the sample index of a sampling rate of 200 samples per cycle and the ordinate indicating the current in Ampere).

The problem of disaggregation of combined electrical loads has been translated to finding that combination of current cycle shapes that, when summed, are most closely (i.e. with minimum error) approximating an actual current cycle shape. Once this combination is found, it is known which appliances have likely been active at the moment the combined current cycle was captured.

A discussion of such approach is given, for example, in the article “Nonintrusive Appliance Load Monitoring” by George W. Hart (Proceedings of the IEEE, Vol. 80, No. 12, December 1992, pages 1870-1891).

The aforementioned way of characterizing current cycle waveshapes is of limited use in cases of loads that have a continuously variable or stochastically variable current characteristic. For example, laptop computers have been observed to exhibit, sometimes even wildly, varying current waveshapes over time. Such a case is illustrated in FIG. 2, in which the waveshapes of two subsequent current cycles for a single laptop are shown. The portions highlighted by circling are substantially different for the two cycles, which originally are consecutive in time.

Such somewhat unpredictable characteristic of one element signal pattern may disrupt the recognition of the overall combination of element signal patterns.

### SUMMARY OF THE INVENTION

It is an object of the present invention to propose a device and a method for disaggregating a periodic input signal pattern like indicated above which allow for a more robust disaggregating and which, in particular, are able to provide recognition of element signal patterns with portions which have deterministically variable or stochastically (non-deterministically) variable values.

This object is achieved by a device for disaggregating a periodic input signal pattern, the input signal pattern resulting from a superposition of element signal patterns corresponding to respective source elements, wherein the device comprises a memory unit which is provided with element information characterizing the element signal patterns, a processing unit for processing the input signal pattern and outputting a processed signal pattern, the processed signal pattern being indicative of a change between portions of the input signal pattern, wherein such portion corresponds to at least a part of the period of the input signal pattern, and an identification unit for identifying a combination of element signal patterns, the superposition of which results in the input signal pattern, using the element information and the processed signal pattern.

The present invention further provides a method for disaggregating a periodic input signal pattern, the input signal pattern resulting from a superposition of element signal patterns corresponding to respective source elements, wherein the method comprises a step of providing element information characterizing the element signal patterns, a step of processing the input signal pattern and outputting a processed signal pattern, the processed signal pattern being indicative of a change between portions of the input signal pattern, wherein such portion corresponds to at least a part of the period of the input signal pattern, and a step of identifying a combination of element signal patterns, the superposition of which results in the input signal pattern, using the element information and the processed signal pattern.

Furthermore, the present invention also provides a computer program including computer program means for causing a device for disaggregating a periodic input signal pattern to carry out the steps of the above method, when the computer program is run on the device. Such computer program may be provided on a data carrier like a memory card or stick or like an optical data carrier like a CD, DVD or BluRay.

The inventor realized that the fact that an element signal pattern may have continuously variable or stochastically variable values in itself may be used for identifying or characterizing such element signal pattern.

In the above case of a laptop current cycle, as illustrated in FIG. 2, it was found by the inventor that some time portions of the current cycle appear to be constant, while other portions are varying over subsequent cycles. This can be seen in FIG. 3, where the single current cycles are plotted vertically over progressive current cycles. Each cycle is represented as 200 samples; wherein a lighter color indicates a more positive current value. In FIG. 3, the presence of horizontal patterns illustrates the present invention: these horizontal patterns indicate that subsequent current cycles, while different, do exhibit common aspects. Some portions of the plot even have the aspect of more or less continuous horizontal lines: these indicate more or less constant current values at certain portions or points inside the current cycle over time. Other portions clearly exhibit variations over subsequent cycles: this variability results in horizontal “noise”, i.e. the plot color varying between grey scale values horizontally.

While the conventional method of finding “the” representative current cycle for such appliance (laptop in this case) will either work not at all or at least not reliably, indeed the variations of the cycle themselves are characteristic to the appliance. Even though the average (e.g. arithmetic mean) of a number of current cycle waveshapes may still provide some information, additional information may be obtained from the variation between different cycles.

According to a particular embodiment, the memory unit is further provided with average information for the element signal patterns corresponding to an average of the respective element signal pattern over plural periods, wherein the identification unit further uses also the average information for identifying. In such embodiment, the device for disaggregating includes functionalities of a conventional device for disaggregating as it is discussed above, while the features of the present invention allow for an increase in versatility, robustness and noise tolerance, for example.

According to a further embodiment, the processing carried out by the processing unit includes at least one of obtaining a pattern based on one or more of the second moment and higher order moments of the portion of the input signal pattern over a plurality of periods, obtaining a frequency transformation of the portion of the input signal pattern over a plurality of periods, performing autocorrelation on the portion of the input signal pattern over a plurality of periods, obtaining a derivative of the portion of the input signal pattern over a plurality of periods, computing a covariance between different portions of the input signal pattern over a plurality of periods, and counting instances of values of the portion of the input signal pattern being above and/or below a respective threshold value over a plurality of periods. It will be appreciated by the skilled reader that the above list is not exhaustive and that in view of needs of an implementation also other kinds of processing may be used, either alone or in combination with the above.

According to yet another embodiment, the processing includes obtaining a pattern indicative of a variance and/or a standard deviation of the portion of the input signal pattern over a plurality of periods. It was found by the inventor that, for example in the context of energy disaggregation, an apparent randomness in a particular portion of a signal of certain source elements gives a strong signature in terms of variance and/or standard deviation, which may advantageously be used for identifying such source element. Furthermore, the variances and standard deviations of the element signal patterns add up to the variance and standard deviation of the input signal pattern, allowing for a simple processing.

According to another embodiment, the input signal pattern is one indicative of power consumption, admittance and/or high-frequency current in a power network in steady-state and/or a transient situation, wherein the source elements are consumer loads and/or supply elements in the power network. One particular use of the present invention is in the area of energy disaggregation, even though the present invention is not limited to such context. In the context of the present invention and energy disaggregation, power source elements (supply elements) with negative overall dissipated power are in no other way different from the power consuming elements and may correspondingly be identified. It is further to be noted that, in a way, reactive or capacitive loads may also be considered as a kind of supply elements, although they only supply energy back during a current cycle that they absorbed before from the same power line.

According to another embodiment, the identification unit is adapted for identifying the combination of element signal patterns, wherein a period of each element signal pattern equals the period of the input signal pattern. For simplicity (as long as the particular use and implementation allows for it), a device or method according to the present invention can base the processing on the assumption that the element signal patterns have the same period (and may additionally be synchronized in their zero-crossings), resulting in an input signal pattern also having such period.

According to yet another embodiment there is provided an indication unit for indicating a combination of source elements corresponding to the identified combination of element signal patterns. By means of such indication unit a user of the device according to such embodiment may easily be informed on the identified source elements.

### BRIEF DESCRIPTION OF THE DRAWINGS

These and other aspects of the invention will be apparent from and elucidated with reference to the embodiments described hereinafter.

In the drawings:

FIG. 1 shows examples of current cycle waveshapes for various electrical appliances,

FIG. 2 shows two examples of a waveshape of two subsequent current cycles for a single laptop,

FIG. 3 shows a diagram displaying current values of single current cycles as a function of progressive cycle index,

FIG. 4 shows an example of a mean current cycle waveshape and the corresponding standard deviation vector for a single laptop, and

FIG. 5 shows an embodiment of a device for disaggregating according to the present invention, and

FIG. 6 illustrates an embodiment of a method for disaggregating according to the present invention.

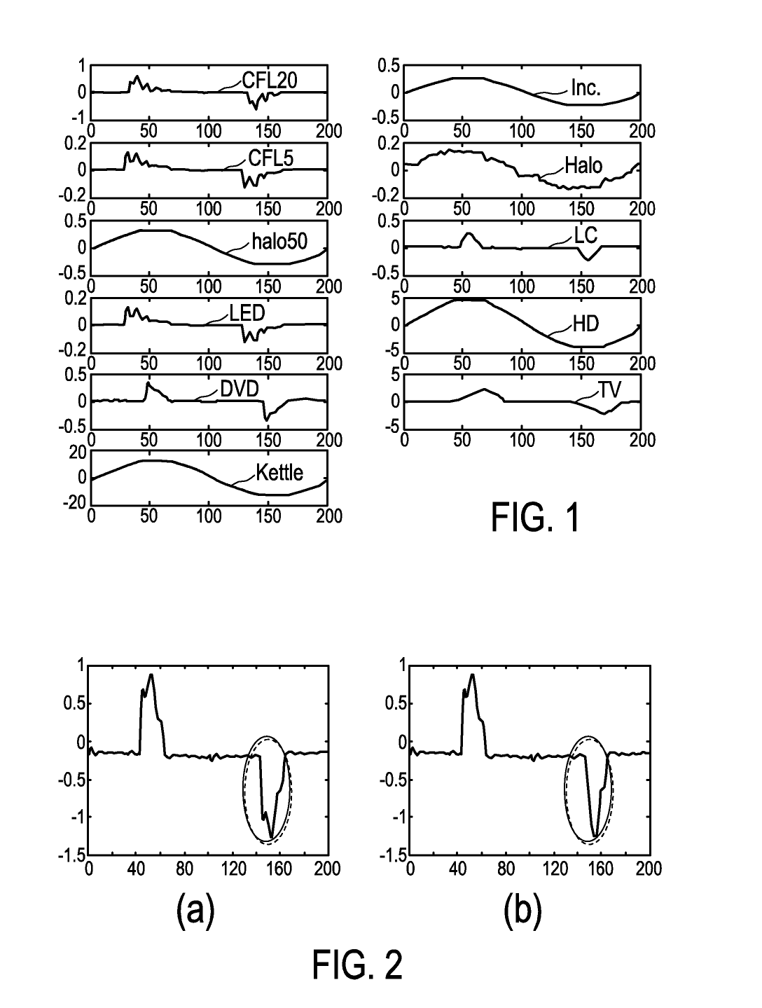

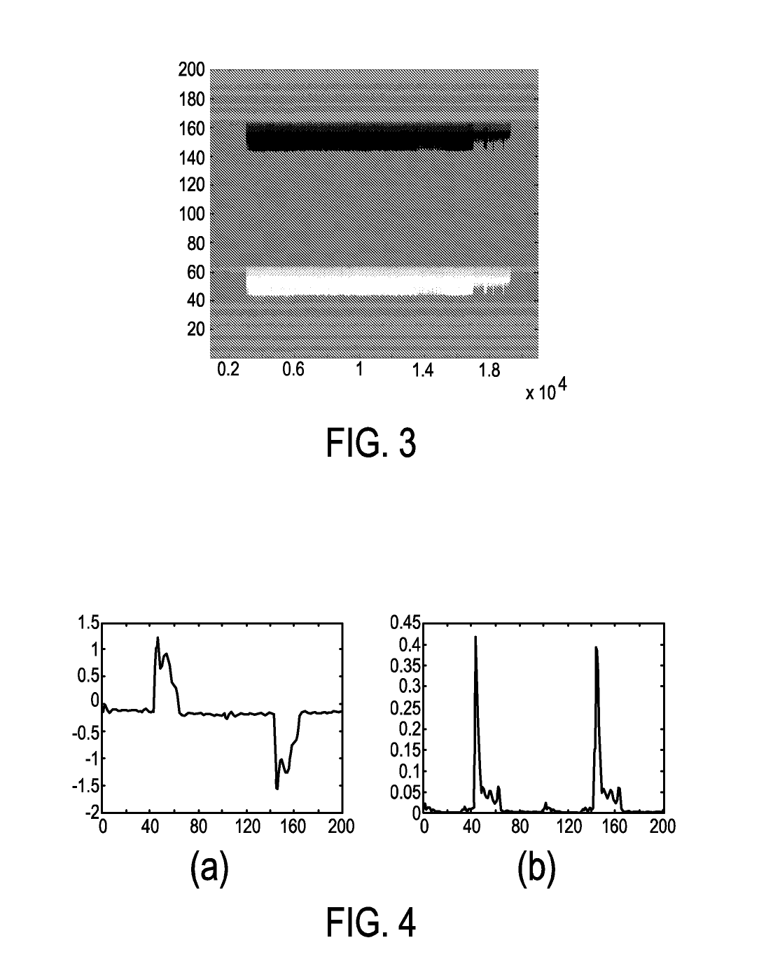

### DETAILED DESCRIPTION OF EMBODIMENTS

FIG. 4 shows an example of a mean current cycle waveshape (a) and the corresponding standard deviation vector (b) for a single laptop. As it may be seen from the illustration of FIG. 4, both waveshapes allow for a characterization of the laptop causing or exhibiting such waveshapes, even though for this case the standard deviation vector may be even more characteristic than the mean pattern. In a theoretical case of an appliance with a constant cycle pattern (e.g. aforementioned constant loads), the mean pattern will equal each single current cycle, and the standard deviation will be zero (no variation over cycles). In practice, however, and in particular for the present laptop case, the standard deviation vector will indicate which current cycle portions are basically constant (almost zero variance) and which are not.

The conventional method of disaggregation by means of using mean values (or patterns) may be combined with the present invention into finding those applications (i.e. current cycle waveshapes) for which the sum of the mean current cycle waveshapes best approximates the aggregate mean current waveshape, and the sum of the current cycle waveshape standard deviation vectors best approximates the aggregate current waveshape standard deviation vector.

The sum of the of the current cycle waveshape standard deviation vectors may be identified with the aggregate current waveshape standard deviation vector as, for practical purposes, the stochastic properties of the current cycles of the various appliances may be assumed to be statistically independent.

In this embodiment, differing from the conventional concept, there are two criteria (errors) to minimize, and various tradeoffs are conceivable. A practical implementation can e.g. minimize a weighted linear sum of both, even though other approaches are apparent to the skilled reader.

In this example, the mean and standard deviation are used as example stochastic attributes. However, the present invention is not limited to these, and also other stochastic or dynamic attributes, such as higher-order moments, can be used in addition or as an alternative.

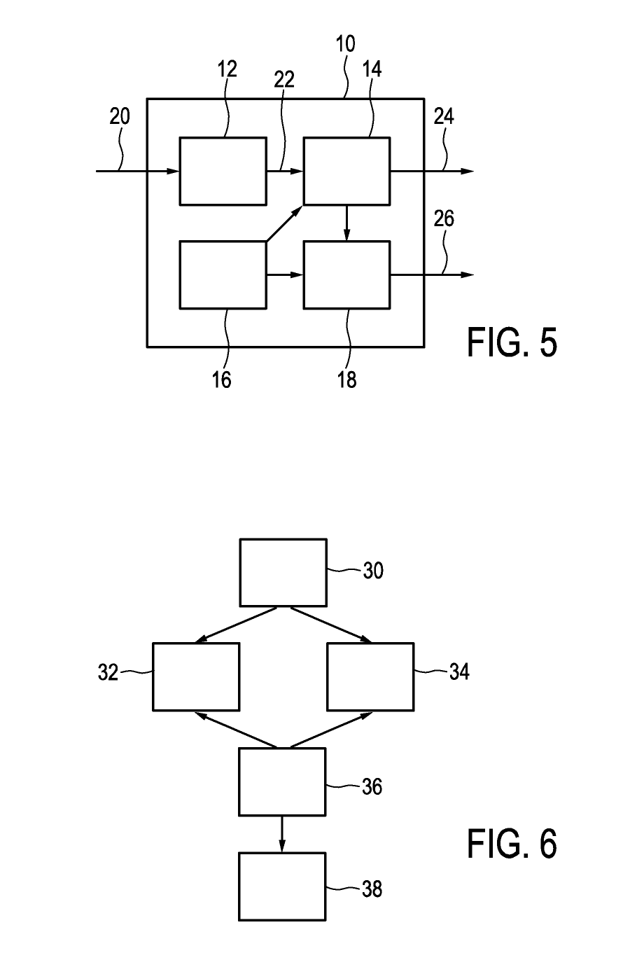

FIG. 5 shows an embodiment of a device for disaggregating according to the present invention. The device 10 for disaggregating includes a processing unit 12, an identification unit 14, a memory unit 16 and an indication unit 18.

As input to the device 10, there is provided an input signal pattern 20, which is received by the processing unit 12. In another implementation, the device may further be equipped with a measuring unit for obtaining the input signal pattern from an external data source or feature, like the current flowing in a power network inside a house. The memory unit 16 includes a database with element information, wherein this information is characterizing element signal patterns which are to be expected as forming the input signal pattern. The processing unit 12 processes the input signal pattern 20 and outputs a processed signal pattern 22. This processed signal pattern 22 indicates of a change between portions of the input signal pattern 20, wherein such portion corresponds to at least a part of the period of the input signal pattern 20 (see for example FIG. 4(b)). The identification unit 14 receives the processed signal pattern from the processing unit 12 and obtains information from the memory unit 16, using these data for identifying a combination of element signal patterns, wherein the superposition of these element signal patterns results in the input signal pattern 20. Principles of such identification, like minimization of errors, are already known from the conventional concepts of disaggregation and may be easily adapted by the person skilled in the art to the present invention. The obtained combination 24 is then output by the identification unit 14 either to the outside or to the indication unit 18, which in turn uses information stored in the memory unit 16 for outputting an indication 26 of the source elements corresponding to such combination 24.

FIG. 6 illustrates an embodiment of a method for disaggregating according to the present invention. In a first step 30, which may be provided independently from the further steps, for example upon manufacturing or configuring a device for carrying out the method, element information characterizing element signal patterns is provided, wherein these element signal patterns are expected as parts of a combination resulting in the input signal pattern. The following step 32 corresponds to the conventional approach of obtaining mean or average values of the input signal pattern of a plurality of cycles or periods. The parallel step 34, however, includes processing the input signal pattern and outputting a processed signal pattern, wherein the processed signal pattern indicates a change between portions of the input signal pattern, wherein such portion corresponds to at least a part of the period of the input signal pattern. In particular, step 34 includes obtaining a pattern indicative of a standard deviation of the portion of the input signal pattern over a plurality of periods (see FIG. 4(b)). Using the previously provided characteristic element information and the obtained data from the input signal pattern, in step 36, a combination of element signal patterns is obtained such that the superposition thereof results in the input signal pattern. In step 38, a combination of source elements corresponding to the identified combination of element signal patterns is indicated.

The term “average” as used herein is not to be understood as being limited to a particular kind of average, like arithmetic mean, geometric mean, harmonic mean, median or mode. Depending on the application area or details of a particular embodiment different “averages” may have different benefits or drawbacks. In particular in the context of energy disaggregation, frequently the arithmetic mean is used, even though other “averages” may also be suited. It is to be noted that other kinds of processing may also be considered as “averaging” in the context of the present invention as long as such “averaging” allows for a sufficient recognition of a characteristic shape or form of a signal and for reducing deviations between different instances of the signal form due to noise or the like.

Even though the above discussion of particular embodiments of the present invention is given in the context of energy disaggregation, it is noted that the present invention is not limited to such context and may be implemented also in other areas. A further example of such implementation is the recognition of human activities (e.g. sports, walking, jogging) using the movement pattern resulting from such activities.

A detailed discussion of the mathematical or algorithmic basis of the disaggregation and processing addressed herein, i.e. finding the combination of current cycle shapes that, when summed, are most closely (i.e. with minimum error) approximating an actual current cycle shape, may be omitted as the skilled person is already sufficiently familiar therewith. In any case, theoretical and practical discussions to this end may also be found in the above mentioned article “Nonintrusive Appliance Load Monitoring” by George W. Hart.

It is to be noted that, strictly speaking, almost all electric appliances have at least two states: ON and OFF, where the OFF state has a zero direct current waveshape. In the above discussing of the embodiments, only the ON state is considered for recognition and the appliance is labeled as stateless, unless otherwise apparent. It is, however, further to be noticed that the present invention is not limited to such steady state case and may also be used in the context of transient signals due to switching on or off of an electric load or supply and corresponding signals in other contexts. Not all appliances have constant load, i.e. constant current waveshape. Certain appliances are characterized by having state behaviour: rather than representing one stationary load (and one current cycle waveshape), they have several different states, where each state has its own characteristic current cycle waveshape. A refrigerator, for example, might dynamically and autonomously switch between a “cooling” and “standby” state over time (maybe with a duration of several minutes per state). Thus, the appliance can still be represented by the set of current cycle waveshapes related to its states and the discussion in the present application is to be understood as also covering such cases.

It is to be noted that the present invention is not limited to only known element patterns and may also be used in the context of a learning approach, where one or more previously unknown pattern are recognized and identified.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

Process steps like processing, identifying or indicating performed by one or several units or devices can be performed by any other number of units or devices. For example, the steps 30 to 38 can be performed by a single unit of by any other number of different units. The steps of the method of the present invention can be implemented as program code means of a computer program and/or as dedicated hardware.

A computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

1. A device for disaggregating a periodic input signal pattern indicative of power consumption, admittance and/or high frequency current in a power network in steady state and/or a transient situation, the input signal pattern resulting from a superposition of element signal patterns corresponding to respective consumer loads and/or supply elements in the power network, the device comprising:
a memory unit which is provided with element information characterizing the element signal patterns based on a continuously variable or stochastically variable value of the element signal patterns,
a processing unit for processing the input signal pattern and outputting a processed signal pattern, the processed signal pattern being indicative of a change between portions of the input signal pattern, wherein such portion corresponds to at least a part of the period of the input signal pattern, and
an identification unit for identifying a combination of element signal patterns, the superposition of which results in the input signal pattern, using the element information and the processed signal pattern.

2. The device according to claim 1, wherein
the memory unit is further provided with average information for the element signal patterns corresponding to an average of the respective element signal pattern over plural periods,
wherein the identification unit further uses also the average information for identifying.

3. The device according to claim 1, wherein
the processing includes at least one of
obtaining a pattern based on one or more of the second moment and higher order moments of the portion of the input signal pattern over a plurality of periods,
obtaining a frequency transformation of the portion of the input signal pattern over a plurality of periods,
performing autocorrelation on the portion of the input signal pattern over a plurality of periods,
obtaining a derivative of the portion of the input signal pattern over a plurality of periods,
computing a covariance between different portions of the input signal pattern over a plurality of periods, and
counting instances of values of the portion of the input signal pattern being above and/or below a respective threshold value over a plurality of periods.

4. The device according to claim 1, wherein
the processing includes obtaining a pattern indicative of a variance and/or a standard deviation of the portion of the input signal pattern over a plurality of periods.

5. (canceled)

6. The device according to claim 1, wherein
the identification unit is adapted for identifying the combination of element signal patterns, wherein a period of each element signal pattern equals the period of the input signal pattern.

7. The device according to claim 1, further comprising
an indication unit for indicating a combination of source elements corresponding to the identified combination of element signal patterns.

8. A method for disaggregating a periodic input signal pattern indicative of power consumption, admittance and/or high frequency current in a power network in steady state and/or a transient situation, the input signal pattern resulting from a superposition of element signal patterns corresponding to respective consumer loads and/or supply elements in the power network, the method comprising:
a step of providing element information characterizing the element signal patterns based on a continuously variable or stochastically variable value of the element signal patterns;
a step of processing the input signal pattern and outputting a processed signal pattern, the processed signal pattern being indicative of a change between portions of the input signal pattern, wherein such portion corresponds to at least a part of the period of the input signal pattern, and
a step of identifying a combination of element signal patterns, the superposition of which results in the input signal pattern, using the element information and the processed signal pattern.

9. A computer program including computer program means for causing a device for disaggregating a periodic input signal pattern to carry out the steps of the method according to claim 8, when the computer program is run on the device.
